(19) United States
(12) Patent Application Publication
(10) Pub. No.: US 2024/0231222 A1
(43) Pub. Date: Jul. 11, 2024

(54) PHOTORESIST COMPOSITION AND METHOD OF FABRICATING SEMICONDUCTOR DEVICE

(71) Applicant: SAMSUNG ELECTRONICS CO., LTD., Suwon-si (KR)

(72) Inventors: Kyungoh KIM, Suwon-si (KR); Sunghyun HAN, Suwon-si (KR); SukKoo HONG, Suwon-si (KR); Moo Hyun KOH, Suwon-si (KR); Haeng Deog KOH, Suwon-si (KR); Yoonhyun KWAK, Suwon-si (KR); Jaemyoung KIM, Suwon-si (KR)

(21) Appl. No.: 18/212,913

(22) Filed: Jun. 22, 2023

(30) Foreign Application Priority Data
Dec. 27, 2022 (KR) 10-2022-0186129

(51) Int. Cl. G03F 7/004; C07F 7/22; H01L 21/027

(52) U.S. Cl. CPC G03F 7/0042; C07F 7/2224; H01L 21/0275; H01L 21/0276

(57) ABSTRACT

Provided is a photoresist composition including an organometallic compound including: a central metal; a first ligand compound; and a second ligand compound, wherein the first ligand compound bonds with the central metal, the second ligand compound does not bond with the central metal, and the first or second ligand compound includes a halogen element. The photoresist composition may improve photosensitivity while securing stability.

### CROSS-REFERENCE TO RELATED APPLICATION

This application claims priority to and the benefit of Korean Patent Application No. 10-2022-0186129 filed in the Korean Intellectual Property Office on Dec. 27, 2022, the entire contents of which are incorporated herein by reference.

### BACKGROUND

### 1. Field

The present disclosure relates to a photoresist composition and a method for fabricating a semiconductor device, and more particularly, to a photoresist composition capable of improving photosensitivity without compromising stability of the photoresist composition and to a method for fabricating a semiconductor device.

### 2. Description of the Related Art

As patterning down-scaling is continuously pursued to improve semiconductor performance, extreme ultraviolet (EUV) lithography, which is an electromagnetic radiation with a wavelength within a range of about 13 nm to about 14 nm, has been introduced. Meanwhile, demand for a photoresist with low dose performance has been increasing to improve productivity. Until now, an organic polymer photoresist composition has been mainly used, but an organic polymer photoresist absorbs about 25% of light at a wavelength of about 13.5 nm, which wastes most of the remaining photons of incident light onto a wafer. In addition, an organic polymer photoresist, when patterned with a narrow line width, may experience a pattern collapse. Accordingly, development of an inorganic photoresist using a metal having a high EUV absorption rate is being carried out as a method for increasing photosensitivity. In particular, a lot of research regarding an organic tin compound having a high absorption rate and satisfying film-forming properties as well as coating properties is being conducted. However there still remain issues such as a lack of storage stability due to moisture reactivity and difficulty in adjusting photosensitivity. In particular, stability of a photoresist composition has a trade-off relationship with photosensitivity, both of which are difficult to simultaneously improve.

### SUMMARY

The photoresist composition according to an aspect may include an organometallic compound that includes a central metal, a first ligand compound, and a second ligand compound, wherein the first ligand compound bonds with the central metal, the second ligand compound does not bond with the central metal, and the first or second ligand compound includes a halogen element.

The photoresist composition according to an aspect may include an organometallic compound including a central metal, a first ligand compound; and a second ligand compound. The first ligand compound may bond with the central metal, the second ligand compound may not bond with the central metal, and both the first ligand compounds and the second ligand compounds may include a halogen element.

A method for fabricating a semiconductor device according to another aspect may include forming a photoresist material layer on a lower layer using the photoresist composition; performing a first bake on the photoresist material layer; performing an exposure by irradiating a KrF excimer laser (248 nm), an ArF excimer laser (193 nm), an F₂ excimer laser (157 nm), or an EUV light (13.5 nm) on a partial region of the photoresist material layer where the first bake is performed, performing a second bake on the photoresist material layer after the exposure, removing an unexposed portion of the photoresist material layer where the second bake is performed to form a photoresist pattern, and processing the lower layer using the photoresist pattern The photoresist composition may include an organometallic compound that includes a central metal, a first ligand compound, and a second ligand compound. The first ligand compound may bond with the central metal, the second ligand compound does not bond with the central metal, and the first ligand compound and/or the second ligand compound may include a halogen element.

### BRIEF DESCRIPTION OF THE DRAWINGS

Features will become apparent to those of skill in the art by describing in detail exemplary embodiments with reference to the attached drawings in which:

FIG. 1 is an illustration depicting a photoresist composition according to Comparative Example 1.

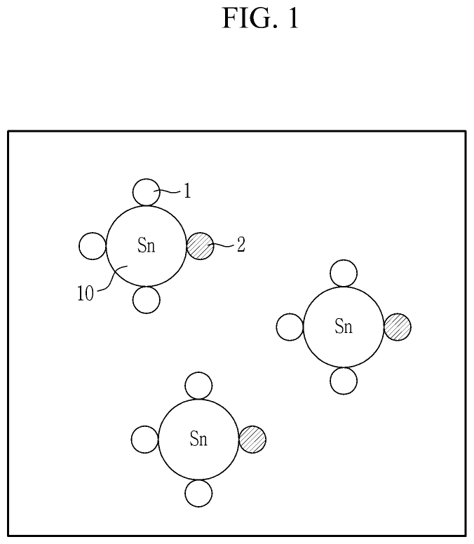

FIG. 2 is an illustration depicting a photoresist composition according to Examples 1 to 4.

FIG. 3 is an illustration depicting a photoresist composition according to Example 5.

FIG. 4 an illustration depicting a photoresist composition according to an example other than Examples 1 to 5.

FIG. 5 is an illustration showing that the stability of a photoresist composition can be improved by blocking a contact of a material capable of undergoing an additional reaction with an organometallic compound, such as moisture or oxygen, by adding an excessive amount of a ligand.

FIG. 6 is a graph showing that the ligand compound (4-iodo-2-methylphenol in this example) including a halogen element used in Examples 1 and 2 generates secondary electrons by irradiation with 13.5 nm light.

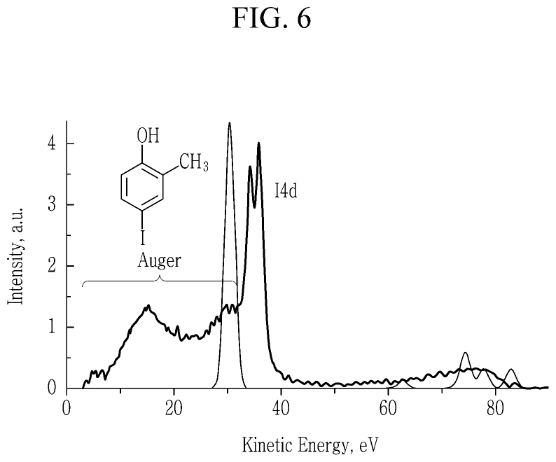

FIG. 7 is a graph showing that a ligand compound (2,3,5,6-tetrafluoro-4-(trifluoromethyl)phenol in this example) including a halogen element generates secondary electrons by 13.5 nm light irradiation.

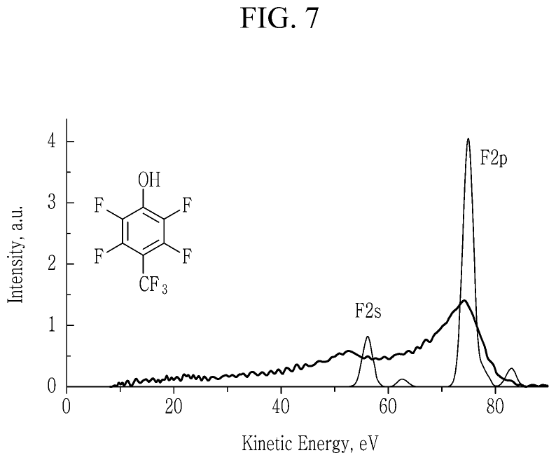

### DETAILED DESCRIPTION

Hereinafter, various embodiments will be described in detail with reference to the accompanying drawings so that those of ordinary skill in the art may easily implement the embodiments. The embodiments may be implemented in various different forms and may not be limited to the embodiments described herein.

The drawings and description are to be regarded as illustrative in nature and not restrictive. Like reference numerals designate like elements throughout the specification.

The size and thickness of each constituent element as shown in the drawings are arbitrarily indicated for better understanding and ease of description, and this disclosure is not necessarily limited to what is shown. In the drawings, the thickness of layers, films, panels, regions, etc., may be exaggerated for clarity. In addition, in the drawings, the thickness of some layers and areas may be exaggerated for better understanding and ease of description.

It is to be understood that when an element such as a layer, film, region, or substrate is referred to as being “on” another element, it can be directly on the other element or intervening elements may also be present. In contrast, when an element is referred to as being “directly on” another element, there are no intervening elements present. The words “on” or “above” refer to being disposed on or below the object portion, and these words do not necessarily refer to being disposed on the upper side of the object portion based on a gravitational direction.

In addition, unless explicitly described to the contrary, the word “comprise”, and variations such as “comprises” or “comprising”, will be understood to imply the inclusion of stated elements but not to the exclusion of any other elements.

Also, throughout the specification, the term “a ligand compound” is meant to include not only one compound but also a mixture of two or more compounds.

Also, throughout the specification, the term “aliphatic carboxylic compound” may refer to a compound including at least one carboxyl group among C1 to C30 aliphatic compounds. The term “aliphatic carboxylic compound” may also refer to a compound that further includes other substituents in addition to the carboxyl group. The aliphatic alkane compound may be a C1 to C30 aliphatic compound. The term “aliphatic alkane compound” may refer to a compound composed of carbon atoms and hydrogen atoms alone. The term “aliphatic ketone compound” may refer to a C1 to C30 aliphatic compound including at least one ketone linking group. the term aliphatic ketone compound may also include a compound further including other substituents in addition to the ketone linking group. The term “aliphatic alcohol compound” may refer to a compound including at least one hydroxyl group among C1 to C30 aliphatic compounds. The term “aliphatic alcohol compound” may also refer to a compound further including other substituents in addition to the hydroxyl group. The term “aliphatic ester compound” may refer to a compound including at least one ester linking group among C1 to C30 aliphatic compounds The term “aliphatic ester compound” may also include a compound further including other substituents in addition to the ester linking group. The term “aliphatic amine compound” may refer to a compound including at least one amine group among C1 to C30 aliphatic compounds. The term “aliphatic amine compound” may also refer to a compound further including other substituents in addition to the amine group. The term “alicyclic carboxyl compound” may refer to a compound including at least one carboxyl group among C1 to C30 alicyclic compounds. The term “alicyclic carboxyl compound” may also include a compound further including other substituents in addition to the carboxyl group. The term “alicyclic alcohol compound” may refer to a compound including at least one hydroxy group among C to C30 alicyclic compounds. The term “alicyclic alcohol compound” may also include a compound further including a substituent other than the hydroxy group. The term “alicyclic ester compound” may refer to a compound including at least one ester linking group among C1 to C30 alicyclic compounds. The term “alicyclic ester compound” may also include a compound further including other substituents in addition to the ester linking group. The term “alicyclic amine compound” may refer to a compound including at least one amine group among C1 to C30 alicyclic compounds. The term “alicyclic amine compound” may also include a compound further including other substituents in addition to the amine group. The term “aromatic compound” may include any compound exhibiting aromaticity. The term “aromatic heterocyclic compound” may refer to a C2 to C30 aromatic heterocyclic compound. The term “aromatic heterocyclic compound” may include all compounds necessarily including at least one heteroatom. the term “fused cyclic compound” may refer to monocyclic or polycyclic cyclic compounds that share linking bonds (e.g., carbon-carbon single bonds, carbon-carbon double bonds, etc.).

A photoresist composition according to an embodiment includes an organometallic compound including: a central metal, a first ligand compound, and a second ligand compound, wherein the first ligand compound bonds with the central metal, the second ligand compound does not bond with the central metal, and the first or second ligand compound includes a halogen element.

The organometallic compound, which is a major component of the organic metal photoresist composition, in general includes a central metal that exhibits high extreme ultraviolet (EUV) absorbance (e.g. Sn, Sb, Te, and Hf) and a ligand compound (for example, a photo-dissociable ligand compound and a hydrolysable ligand compound) bonded to the central metal. When exposed to light, the ligand compound may be dissociated in a radical form by a photoreaction and thus may form a metal oxide by a condensation reaction between OH groups generated there. (Refer to Reaction Scheme 1 below). For example, in Reaction Scheme 1, R may be the photo-dissociable ligand compound, and X may be the hydrolysable ligand compound.)

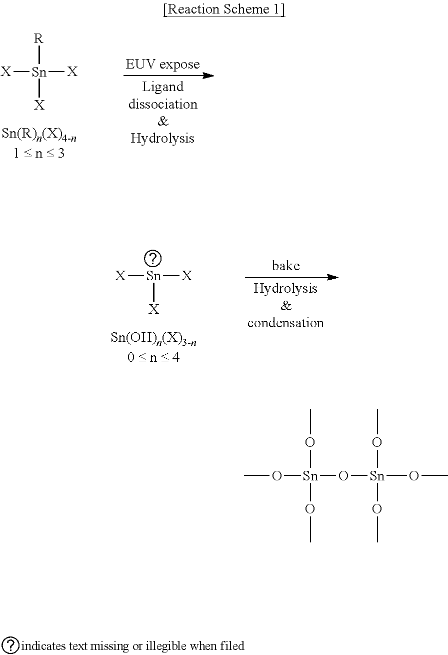

Accordingly, in order to secure the stability of the photoresist composition, the ligand compound needs to be firmly bonded to the central metal without dissociation. In order to increase the photosensitivity, a dissociation rate of the ligand compound needs to be increased, which puts the stability and the photosensitivity of the photoresist composition in the trade-off relationship with each other. Accordingly, the stability and the photosensitivity of the photoresist composition including the organometallic compound may be very difficult to improve simultaneously.

Both the photo-dissociable ligand compound and the hydrolysable ligand compound are ligand compounds bonded to a central metal in an organometallic compound. The ligand compounds may have one or more binding sites bonded to the central metal in one molecule. The ligand compounds may be, for example, butane, cyclohexane, benzylidene, 8-hydroxyquinoline, propionic acid, acetic acid, acetyl acetone, sulfuric acid, camphoric acid, etc., as non-limiting examples.

The present inventors have clearly recognized the aforementioned conventional difficulty and after making numerous efforts to resolve the difficulty, it has been confirmed that the ligand compound bonded to the central metal in the organometallic compound structurally includes no halogen element. In addition, it has been confirmed that there was no excess ligand compound that was not bonded to the central metal. As a result of repeating studies based on these configurations, the stability and the photosensitivity of the photoresist composition was simultaneously secured by adding the ligand compound in an excessive amount to react with the organometallic compound and necessarily generate the excess ligand compound and in addition, by controlling a composition of the ligand compound such that either one of the ligand compound bonded to the central metal of the organometallic compound and the excess ligand compound might include the halogen element, which is known to be an extreme ultraviolet (EUV) absorbing element.

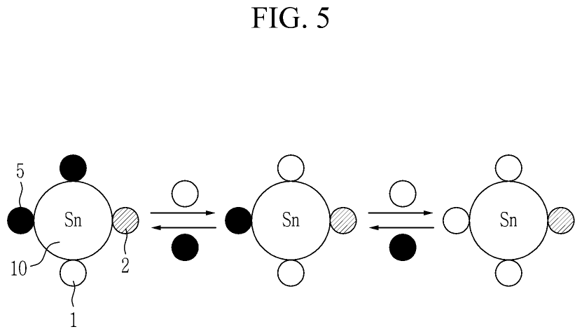

The excess ligand compound may not be bonded to the central metal of the organometallic compound but may be present in the periphery to prevent a reaction with water physically or through chemical equilibrium and may serve to help the ligand compound bonded to the central metal of the organometallic compound be more stably bonded to the central metal. Referring to FIG. 5, the hydrolysable ligand compound may be added in an excessive amount thereto to prevent moisture or oxygen from bonding with tin, with the central metal, or with the organometallic compound through the chemical equilibrium reaction. Instead, the hydrolysable ligand compound may be added in an excessive amount to the tin, the central metal, to help the ligand compound be more stably bonded to the tin, which ultimately improves the stability of the photoresist composition and as a result, reduces changes over time.

However, as described above, the ligand compound may be more stably bonded to the central metal and may increase the stability of the photoresist composition. However, there is a possibility of deteriorating the photosensitivity of the photoresist composition. This problem has been addressed by using a ligand compound including a halogen element. The ligand compound including the halogen element by itself may generate secondary electrons to increase a photoreaction rate or to affect binding energy between the ligand compound and the central metal to increase the photoreaction rate. For example, since the ligand compound including the halogen element generates radicals when exposed to light, the efficiency of generating the secondary electrons when exposed to extreme ultraviolet (EUV) may be greatly improved, even when extreme ultraviolet light (EUV) is irradiated onto an organometallic compound in which a ligand compound including no halogen element and a central metal are bonded The secondary electrons may be emitted, but their generation efficiency may be insignificant. According to one aspect, the ligand compound may generate the secondary electrons with very high efficiency through the extreme ultraviolet (EUV) exposure In addition, the ligand compound may also generate the radicals and thus greatly increase the photoreaction rate. Since the radicals and the secondary electrons exposure increase the photoreaction rate through extreme ultraviolet light (EUV) without deteriorating the stability of the photoresist composition, which is achieved by the excess ligand compound, the photoresist composition according to one aspect may simultaneously improve the stability and the photosensitivity.

For example, the ligand compound including the halogen element may be a first ligand compound or a second ligand compound.

The ligand compound including a halogen element may be deemed to be the second ligand compound.

For example, among the first ligand compound and the second ligand compound, the second ligand compound may include a halogen element.

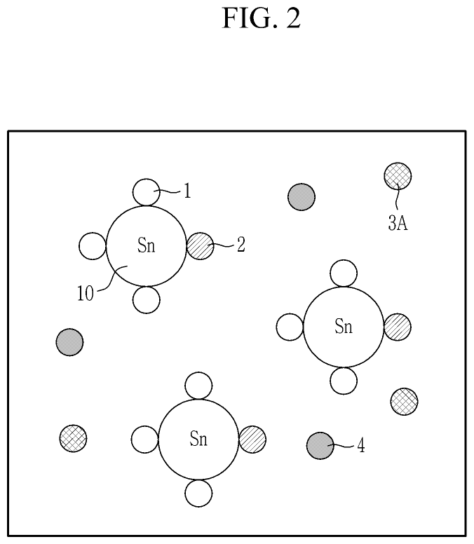

Referring to FIG. 2, the photoresist composition according to an aspect may include tin as a central metal constituting the organometallic compound 10, a first ligand compound bonded to the tin, and a second ligand compound not bonded to the tin, wherein the first ligand compound bonded to the tin includes a hydrolysable ligand compound 1 and a photo-dissociable ligand compound 2. In addition, a ligand compound 3A including a halogen element may be present as the second ligand compound which forms no bond with the central metal, tin. The second ligand compound may also include a ligand compound 4 not including the halogen element as well as the ligand compound 3A that includes the halogen element. In other words, the second ligand compound may further include the ligand compound 4, which does not include the halogen element in addition to the ligand compound 3A that includes the halogen element.

For example, the second ligand compound including the halogen element may include at least one selected from an aliphatic carboxyl compound, an aliphatic alkane compound, an aliphatic alcohol compound, an aliphatic ester compound, an aliphatic amine compound, an alicyclic carboxyl compound, an alicyclic alcohol compound, an alicyclic ester compounds, an alicyclic amine compound, an aromatic compound, and a fused ring compound. However, when the halogen element is included, the type is not particularly limited.

For example, the second ligand compound including the halogen element may include trifluoroacetic acid, iodo alcohol, fluorobenzene, iodo n-butane, 1-ethyl-4-iodobenzene, 1,4-diiodooctane, 2-iodoethanol, 4-iodo-2-methylphenol, 2,3,5,6-tetrafluoro-4-(trifluoromethyl)phenol, 2-(5-fluoro-2-methoxyphenyl)acetic acid), as non-limiting examples.

For example, among the second ligand compounds, the ligand compound that does not include a halogen element may include a heteroatom other than a halogen element.

For example, a second ligand compound including a heteroatom other than a halogen element may include at least one selected from sulfuric acid, phosphoric acid, an aliphatic carboxyl compound, an aliphatic ketone compound, an aliphatic alcohol compound, an aliphatic ester compound, an aliphatic amine compound, an alicyclic carboxyl compound, an alicyclic ketone compound, an alicyclic alcohol compound, an alicyclic ester compound, an alicyclic amine compound, an aromatic heterocyclic compound, and a fused ring compound. However, when the halogen element is included, the ligand compound is not particularly limited. As long as the heteroatom-containing compound does not include a halogen element, the type is not particularly limited.

For example, the second ligand compound including a heteroatom other than a halogen element may include hexanoic acid, butane, acetic acid, tetrahydro quinoline, 8-hydroxyquinoline, propionic acid, acetyl acetone, sulfuric acid, phosphoric acid, camphoric acid, etc., as non-limiting examples.

For example, when the ligand compound that includes a halogen element is the second ligand compound, the first ligand compound does not include a halogen element. Herein, the first ligand compound may not include the halogen element but may have one or more binding sites that are capable of bonding with the central metal constituting the organometallic compound. A structure thereof is not particularly limited. For example, the first ligand compound may be the same as the second ligand compound including a heteroatom other than the halogen element. A carbon atom or a heteroatom (oxygen atom, nitrogen atom, sulfur atom, phosphorus atom, etc.) constituting the first ligand compound may form a bond (covalent bond, coordination bond, ionic bond, etc. as non-limiting examples) to the central metal. For example, the first ligand compound may be composed of a carbon atom and a hydrogen atom alone without including the halogen element and the heteroatom. The first ligand compound composed of the carbon atom and the hydrogen atom alone may include at least one selected from an alicyclic compound, an aromatic compound, and a fused ring compound, such as, for example, cyclohexane, benzylidene, butane, and the like, as non-limiting examples.

### (When the Ligand Compound Including a Halogen Element is the First Ligand Compound)

For example, among the first ligand compound and the second ligand compound, the first ligand compound may include a halogen element.

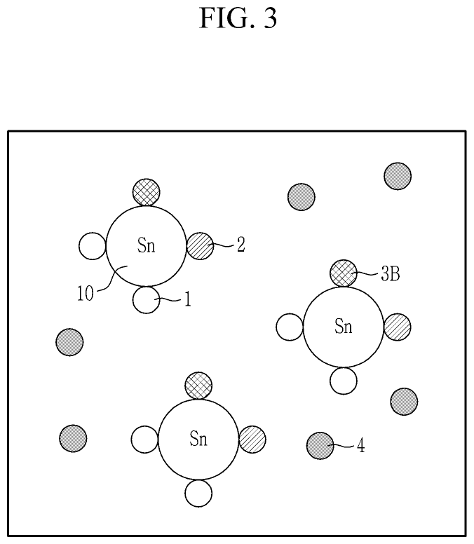

Referring to FIG. 3, the photoresist composition according to one aspect may include tin, a central metal constituting the organometallic compound, the first ligand compound bonded to the tin, and the second ligand compound not bonded to the tin, wherein the first ligand compound bonded to the tin includes a ligand compound 3B including the hydrolysable ligand compound 1, the photo-dissociable ligand compound 2, and the halogen element. In other words, the ligand compound 3B including the halogen element may be bonded to the central metal, tin. In addition, the second ligand compound not bonded to the central metal, tin, may be all composed of a ligand compound 4 including no halogen element. In other words, the first ligand compound may further include a ligand compound that does not include the halogen element (hydrolysable ligand compound 1, photo-dissociable ligand compound 2, etc.) in addition to the ligand compound 3B including the halogen element, wherein the second ligand compound may be composed of the ligand compound 4 including no halogen element.

For example, the first ligand compound including the halogen element 3B may include at least one selected from an aliphatic carboxyl compound, an aliphatic alkane compound, an aliphatic alcohol compound, an aliphatic ester compound, an aliphatic amine compound, an alicyclic carboxyl compound, an alicyclic alcohol compound, an alicyclic ester compounds, an alicyclic amine compound, an aromatic compound, and a fused ring compound. When the halogen element is included, the type is not particularly limited.

For example, the first ligand compound including the halogen element may include trifluoroacetic acid, iodo alcohol, fluorobenzene, iodo n-butane, 1-ethyl-4-iodobenzene, 1,4-diiodooctane, 2-iodoethanol, 4-iodo-2-methylphenol, 2,3,5,6-tetrafluoro-4-(trifluoromethyl) phenol), fluorobenzene, and the like, as non-limiting examples.

For example, among the atoms constituting the first ligand compound including the halogen element, a carbon atom and/or a heteroatom (oxygen atom, nitrogen atom, sulfur atom, phosphorus atom, etc.) may form a bond (covalent bond, coordination bond, ionic bond, etc. but the type is not limited) with the central metal.

For example, among the first ligand compounds, the ligand compound not including the halogen element may include a heteroatom other than a halogen element or the ligand compound may be composed of carbon atoms and hydrogen atoms alone. For example, the hydrolysable ligand compound 1 and the photo-dissociable ligand compound 2 included in the ligand compound and not including the halogen element among the first ligand compounds may include at least one selected from sulfuric acid, phosphoric acid, an aliphatic carboxyl compound, an aliphatic ketone compound, an aliphatic alcohol compound, an aliphatic ester compound, an aliphatic amine compound, an alicyclic carboxyl compound, an alicyclic ketone compound, an alicyclic alcohol compound, an alicyclic ester compound, an alicyclic amine compound, an aromatic heterocyclic compound, and a fused ring compound. For example, as described above, the first ligand compound may be butane, cyclohexane, benzylidene, 8-hydroxyquinoline, propionic acid, acetic acid, acetyl acetone, sulfuric acid, camphoric acid, etc., as non-limiting examples.

For example, when the ligand compound including the halogen element is the first ligand compound, the second ligand compound does not include the halogen element. At this time, the second ligand compound does not include a halogen element and does not form a bond with the central metal constituting the organometallic compound, and its structure is not particularly limited. For example, the second ligand compound may be the same as the first ligand compound including the heteroatom other than the halogen element, or the second ligand compound may be the same as the first ligand compound composed of carbon atoms and hydrogen atoms alone. A carbon atom or a heteroatom (oxygen atom, nitrogen atom, sulfur atom, phosphorus atom, etc.) constituting the second ligand compound may form a bond (covalent bond, coordination bond, ionic bond, etc. as non-limiting examples) with the central metal.

For example, the central metal may be a metal having high extreme ultraviolet (EUV) absorption, and may include one or more selected from metals such as polonium (Po), tellurium (Te), titanium (Ti), lead (Pb), gold (Au), silver (Ag), cesium (Cs), bismuth (Bi), tin (Sn), hafnium (Hf), zinc (Zn), cobalt (Co), aluminum (Al), antimony (Sb), indium (In), cadmium (Cd), and astatine (At), as non-limiting examples.

For example, a total amount of the organometallic compound including the central metal, the first ligand compound, and the second ligand compound may be less than or equal to about 5 wt %, for example about 0.1 wt % to about 5 wt %, for example about 0.5 wt % to about 5 wt %, or for example about 1 wt % to about 5 wt % based on the total amount of the photoresist composition. If the total amount of the organometallic compound, the first ligand compound, and the second ligand compound were to be too small, the effect of the addition of the organometallic compound, the first ligand compound, and the second ligand compound could be insufficient, and if the total amount of the organometallic compound, the first ligand compound, and the second ligand compound were to be too large, the resolution of the pattern could be excessively reduced.

The photoresist composition according to one aspect may further include a solvent.

The solvent may include, for example, distilled water, an aprotic polar solvent, or a combination thereof. When the distilled water and the aprotic polar solvent are used together as the solvent, the stability of the photoresist composition may be further improved.

The aprotic polar solvent may be, for example, at least one selected from acetone, acetonitrile, dimethyl acetamide (DMAc), dimethyl formamide (DMF), diethyl formamide (DEF), dimethyl sulfoxide (DMSO), methyl ethyl ketone, methyl n-propyl ketone, N-methylpyrrolidone (NMP), propylene carbonate, nitromethane, sulfolane, and hexamethylphosphoramide (HMP).

The solvent may include an organic solvent other than the above-mentioned solvent, such as, for example, ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, 2-hydroxyethylpropionate, 2-hydroxy-2-methylethylpropionate, ethoxy ethyl acetate, hydroxyethyl acetate, 2-hydroxy-3-methylbutanoate, 3-methoxy methyl propionate, 3-methoxy ethyl propionate, 3-ethoxy ethyl propionate, 3-ethoxy methyl propionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxy ethoxy propionate, ethoxy, ethoxy propionate, or a combination thereof.

The solvent may be included in an amount of, for example, greater than or equal to about 95 wt %, or, for example, about 95 wt % to about 99.9 wt %, or, for example, about 95 wt % to about 99.5 wt %, or, for example, about 95 wt % to about 99 wt %.

The photoresist composition according to one aspect may further include at least one selected from a surfactant, a dispersant, a moisture absorbent, and a coupling agent.

The surfactant may serve to improve coating uniformity and wettability of the photoresist composition. In example embodiments, the surfactant may be a sulfuric acid ester salt, a sulfonic acid salt, a phosphoric acid ester, a soap, an amine salt, a quaternary ammonium salt, polyethylene glycol, an alkylphenol ethylene oxide adduct, a polyhydric alcohol, a nitrogen-containing vinyl polymer, or a combination thereof, as non-limiting examples. The surfactant may include, for example, an alkylbenzenesulfonic acid salt, an alkylpyridinium salt, polyethylene glycol, or a quaternary ammonium salt. When the photoresist composition includes the surfactant, the surfactant may be included in an amount of about 0.001 wt % to about 3 wt % based on the total weight of the photoresist composition.

The dispersant may serve to uniformly disperse in the photoresist composition each component constituting the photoresist composition. In example embodiments, the dispersant may be an epoxy resin, polyvinyl alcohol, polyvinyl butyral, polyvinylpyrrolidone, glucose, sodium dodecyl sulfate, sodium citrate, oleic acid, linoleic acid, or a combination thereof, as non-limiting examples. When the photoresist composition includes the dispersant, the dispersant may be included in an amount of about 0.001 wt % to about 5 wt % based on the total weight of the photoresist composition.

The moisture absorbent may serve to prevent a weakening effect that moisture can have on a photoresist composition. For example, the moisture absorbent may serve to prevent the organometallic compound included in the photoresist composition from being oxidized by moisture. The moisture absorbent may be, for example, polyoxyethylene nonylphenol ether, polyethylene glycol, polypropylene glycol, polyacrylamide, or a combination thereof, as non-limiting examples. When the photoresist composition includes the moisture absorbent, the moisture absorbent may be included in an amount of about 0.001 wt % to about 10 wt % based on the total weight of the photoresist composition.

The coupling agent may serve to improve a close-contacting force with the lower layer when the photoresist composition is coated on the lower layer. For example, the coupling agent may include a silane coupling agent. The silane coupling agent may include vinyltrimethoxysilane, vinyltriethoxysilane, vinyl trichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyl dimethoxysilane, 3-methacryloxypropylmethyldiethoxysilane, or trimethoxy [3-(phenyl amino)propyl]silane, as non-limiting examples. When the photoresist composition includes the coupling agent, the coupling agent may be included in an amount of about 0.001 wt % to about 5 wt % based on the total weight of the photoresist composition.

### (When the Ligand Compound Including a Halogen Element is a First Ligand Compound and a Second Ligand Compound)

The photoresist composition according to an example embodiment may include an organometallic compound including: a central metal; a first ligand compound; and a second ligand compound, wherein the first ligand compound bonds with the central metal, the second ligand compound does not bond with the central metal, and both the first and second ligand compound include a halogen element.

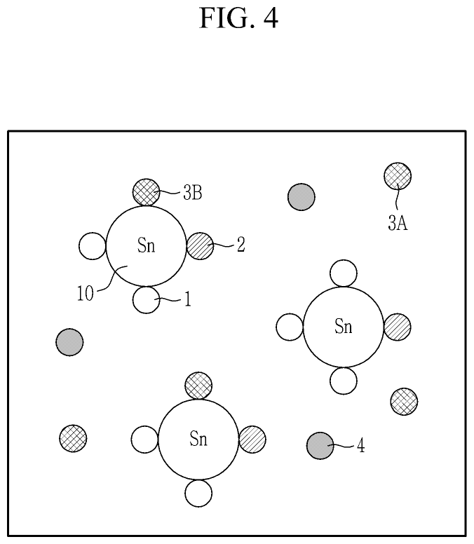

Referring to FIG. 4, the photoresist composition according to an aspect may include tin, a central metal constituting the organometallic compound, the first ligand compound bonded to the tin, and the second ligand compound not bonded to the tin, wherein the first ligand compound bonded to the tin includes the ligand compound 3B including the hydrolysable ligand compound 1, the photo-dissociable ligand compound 2, and the halogen element. In addition, the second ligand compound not bonded to the tin, a central metal, may include the ligand compound 3A including the halogen element and the ligand compound 4 not including a halogen element. In other words, the term first ligand compound may further encompass a ligand compound that does not include the halogen element (hydrolysable ligand compound 1, photo-dissociable ligand compound 2, etc.) in addition to the ligand compound 3B including the halogen element. The second ligand compound may further include the ligand compound 4 that does not include the halogen element and the like in addition to the ligand compound 3A including the halogen element.

Descriptions of each case where the organometallic compound, the first ligand compound, and the second ligand compound respectively include the halogen element or don't include the halogen element may be the same as described above and accordingly, will not be repeated.

According to another aspect, a method of fabricating a semiconductor device using the photoresist composition according to the technical spirit thereof is provided. Specifically, a method for fabricating a semiconductor device according to another aspect may include: forming a photoresist material layer on a lower layer using the photoresist composition; performing a first bake on the photoresist material layer; performing exposure by irradiating a KrF excimer laser (248 nm), an ArF excimer laser (193 nm), an F₂ excimer laser (157 nm), or an EUV light (13.5 nm) on a partial region of the photoresist material layer where the first bake is performed; performing a second bake on the photoresist material layer after the exposure; removing an unexposed portion of the photoresist material layer where the second bake is performed to form a photoresist pattern; and processing the lower layer using the photoresist pattern, wherein the photoresist composition includes an organometallic compound including a central metal, a first ligand compound, and a second ligand compound, and wherein the first ligand compound bonds with the central metal, the second ligand compound does not bond with the central metal, and the first ligand compound and/or second ligand compound include a halogen element.

The semiconductor device may be, for example, an integrated circuit device. Hereinafter, a method of fabricating the integrated circuit device according to an embodiment will be described in detail.

First, a feature layer is formed on a substrate, and a photoresist layer is formed on the feature layer using the photoresist composition according to an aspect.

As described above, the photoresist layer may include the organometallic compound, the first ligand compound, and the second ligand compound. A more detailed configuration of the photoresist composition may be as described above.

The substrate may include a semiconductor substrate. The feature layer may be an insulating layer, a conductive layer, or a semiconductor layer. For example, the feature layer may be made of a metal, an alloy, a metal carbide, a metal nitride, a metal oxynitride, a metal oxycarbide, a semiconductor, polysilicon, an oxide, a nitride, an oxynitride, or a combination thereof, as non-limiting examples.

In some implementations, a lower layer may be formed on the feature layer before forming the photoresist layer on the feature layer. In this case, the photoresist layer may be formed on the lower layer. The lower layer may serve to prevent adverse effects that the photoresist layer could receive from the lower feature layer. For example, the lower layer may be made of an organic or inorganic anti-reflective coating (ARC) material for KrF excimer lasers, ArF excimer lasers, EUV lasers, or any other light source. For example, the lower layer may be formed of a bottom anti-reflective coating (BARC) layer or a developable bottom anti-reflective coating (DBARC) layer. Meanwhile, the lower layer may include an organic component having a light absorption structure. The light absorption structure may be, for example, a hydrocarbon compound having one or more benzene rings or a structure in which benzene rings are fused. The lower layer may be formed to a thickness of about 1 nm to about 100 nm, as a non-limiting example. For example, the lower layer may be omitted.

In order to form the photoresist layer, the photoresist composition according to one aspect may be coated on the lower layer. The coating may be performed by a method such as spin coating, spray coating, or dip coating. The thickness of the photoresist layer may be several tens to several hundred times the thickness of the lower layer. The photoresist layer may be formed to a thickness of about 10 nm to about 1 μm, as non-limiting examples.

A first bake may be performed for the photoresist layer. The first bake may also be referred to as a post apply bake (PAB).

The first bake may be performed at a temperature of about 80° C. to about 180° C., or about 90° C. to about 160° C., for about 10 seconds to about 100 seconds. If the temperature of the first bake were to be too low, solvent removal could be insufficient. If the temperature of the first bake were to be too high, resolution of the photoresist pattern could deteriorate.

By exposing the photoresist layer to light, radicals and secondary electrons may be generated from halogen elements in the photoresist composition. At this time, the whole surface of the photoresist layer may not be exposed, but a partial region may be exposed such that a non-exposed region is provided.

As an example, in order to expose the photoresist layer, a photomask having a plurality of light shielding areas (LS) and a plurality of light transmitting areas (LT) may be aligned at a predetermined position on the photoresist layer. Then, through the plurality of light transmitting areas (LT) of the photomask, the photoresist layer may be exposed. The exposure of the photoresist layer may be performed by using a KrF excimer laser (about 248 nm), an ArF excimer laser (about 193 nm), an F₂ excimer laser (about 157 nm), or an EUV laser (about 13.5 nm). For example, depending on a type of the light sources, a reflective photomask may be used instead of a transmissive photomask. Hereinafter, the transmissive photomask is mainly described, but those skilled in the art will understand that the reflective photomask may be used for the exposure by an equivalent configuration.

The photomask may include a transparent substrate and a plurality of light-blocking patterns formed in the plurality of light-blocking areas (LS) on the transparent substrate. The transparent substrate may be made of quartz. The plurality of light-blocking patterns may be formed of chromium (Cr). The plurality of light transmitting areas (LT) may be defined by the plurality of light-blocking patterns. According to an embodiment, in order to expose the photoresist layer, a reflective photomask for extreme ultraviolet (EUV) exposure may be used instead of the above-described photomask.

In some implementations, an extreme ultraviolet (EUV) exposure apparatus may include an extreme ultraviolet (EUV) light source, an illumination optical system, a photomask support, a projection optical system, and a substrate stage.

The extreme ultraviolet (EUV) light source may generate and output EUV light (EL) having a high energy density. For example, the EUV light (EL) emitted from the EUV light source may have a wavelength of about 4 nm to about 124 nm. For example, the EUV light (EL) may have a wavelength of about 4 nm to about 20 nm or a wavelength of about 13.5 nm.

The EUV light source may be a plasma light source or a synchrotron radiation light source. Herein, the term “plasma light source” may refer to a light source that produces plasma and uses light emitted by the plasma. For example, the plasma light source may include a laser produced plasma light source, a discharge produced plasma light source, or the like.

The EUV light source may include a laser light source, a transmission optical system, a vacuum chamber, a collector mirror, a droplet generator, and a droplet catcher.

The laser light source may be configured to output a laser. For example, the laser light source may output a carbon dioxide laser. The laser output from the laser light source may be incident into a window of a vacuum chamber through a plurality of reflective mirrors in the transmission optical system, and then may be introduced into the vacuum chamber.

At the center of the collector mirror, an aperture through which the laser is introduced into the vacuum chamber may be formed.

The droplet generator may interact with a laser to generate droplets generating EUV light (EL) and provide the droplets into the vacuum chamber. The droplets may include at least one out of tin (Sn), lithium (Li), and xenon (Xe). For example, the droplets may include at least one of tin (Sn), a tin compound (e.g., SnBr₄, SnBr₂, SnH), or a tin alloy (e.g., Sn—Ga, Sn—In, Sn—In—Ga).

The droplet catcher may be located below the droplet generator and configured to collect the droplets that do not react with the laser (OL). The droplets provided from the droplet generator may react with the laser (OL) introduced into the vacuum chamber and may generate EUV light (EL). The collector mirror may collect and reflect EUV light (EL) and thus may emit the EUV light (EL) into the illumination optical system outside of the vacuum chamber.

The illumination optical system may include the plurality of reflective mirrors and may transfer the EUV light (EL) emitted from the EUV light source to an EUV photomask (PM). For example, the EUV light (EL) emitted from the EUV light source may be reflected by the reflective mirrors in the illumination optical system and then, may be incident onto the EUV photomask (PM) disposed on the photomask support.

The EUV photomask (PM) may be a reflective mask that has a reflective region and a non-reflective (or intermediate reflective) region. The EUV photomask (PM) may include a reflective multilayer film formed on a mask substrate. The mask substrate may be formed of a material having a low thermal expansion coefficient such as silicon (Si) and an absorption pattern formed on the reflective multilayer film. The reflective multilayer film may correspond to the reflective region, and the absorption pattern may correspond to the non-reflective (or intermediate reflective) region.

The EUV photomask (PM) may reflect the EUV light (EL) that is incident through the illumination optical system and the EUV light (EL) may be incident into the projection optical system. In more detail, the EUV photomask (PM) may structure incident light from the illumination optical system into projection light, based on a pattern formed by the reflective multilayer film and the absorption pattern on the mask substrate such that the incident light becomes incident into the projection optical system. The projection light may be structured through at least a second diffraction order based on the EUV photomask (PM). This projection light may retain information regarding a pattern shape of the EUV photomask (PM) and the projection light may be incident into the projection optical system, and then may pass through the projection optical system and form an image corresponding to the pattern shape of the EUV photomask (PM) on the substrate.

The projection optical system may include a plurality of reflective mirrors. For example, the projection optical system may in general include at least two reflective mirrors or, for example, four to eight reflective mirrors. The number of the reflective mirrors included in the projection optical system is not limited to the above numbers.

The substrate may be disposed on the substrate stage.

When EUV light is used, a light dose sufficient for the exposure may be calculated to check the photosensitivity of the photoresist composition. In other words, the smaller the dose, the better the photosensitivity.

After the photoresist layer is exposed, the photoresist layer may be secondarily baked. The second baking may be called post exposure baking (PEB). The second baking may be performed at about 50° C. to about 400° C. for about 10 seconds to about 100 seconds as a non-limiting example.

Specifically, the second baking promotes an extensive reaction among the organometallic compound, the first ligand compound, and the second ligand compound.

Subsequently, the photoresist layer may be developed by using a developing solution to remove the non-exposed region of the photoresist material layer. As a result, the photoresist pattern made up of the exposed region of the photoresist layer may be formed.

The photoresist pattern may include a plurality of openings. After forming the photoresist pattern, a lower pattern may be formed by removing a portion of a lower layer exposed through the plurality of openings.

For example, the development of the photoresist layer may be performed in an NTD (negative-tone development) process. In this process, the developing solution may include propylene glycol monomethyl ether acetate or 2-heptanone, as non-limiting examples.

In the photoresist layer, since the exposed region and the unexposed region have a larger solubility difference with regard to the developing solution, while the unexposed region is removed by developing the photoresist layer, the exposed region may not be removed but may remain. Accordingly, after developing the photoresist layer, a vertical pillar pattern sidewall profile in the photoresist pattern may be obtained without residual defects such as footing and the like.

The photoresist pattern may be used to process the feature layer.

In order to process the feature layer, various processes such as a process of etching the feature layer exposed through the openings of the photoresist pattern, a process of injecting impurity ions into the feature layer, a process of forming an additional film on the feature layer through the openings, a process of transforming a portion of the feature layer through the openings, and the like, may be performed.

For example, the formation process of the feature layer may be omitted, and the substrate may be processed by using the photoresist pattern. For example, various processes such as a process of etching a portion of the substrate by using the photoresist pattern, a process of injecting impurity ions into a portion of the substrate, a process of forming an additional layer on the substrate through the openings, a process of transforming the portion of the substrate, or the like, may be performed.

Subsequently, the remaining photoresist pattern and the lower pattern may be removed. In order to remove the photoresist pattern and the lower pattern, an ashing process and a strip process may be used.

The following Examples and Comparative Examples are provided in order to highlight characteristics of one or more embodiments. It is to be understood that the Examples and Comparative Examples are not to be construed as limiting the scope of the embodiments, nor are the Comparative Examples to be construed as being outside the scope of the embodiments. Further, it is to be understood that the embodiments are not limited to the particular details described in the Examples and Comparative Examples.

### Comparative Examples 1 to 3 and Examples 1 to 5

### Comparative Example 1

A photoresist composition including a metal compound represented by Sn(R)₁(X)₃ (where R is a butyl group, and X is acetic acid) and propylene glycol monomethyl ether acetate was prepared by using tin oxide (II), a photo-dissociable ligand compound (butane), and a hydrolysable ligand compound (acetic acid). The acetic acid may be linked to the tin in any one of Chemical Formulas L-1 to L-4. (* indicates a portion directly linked to the tin.)

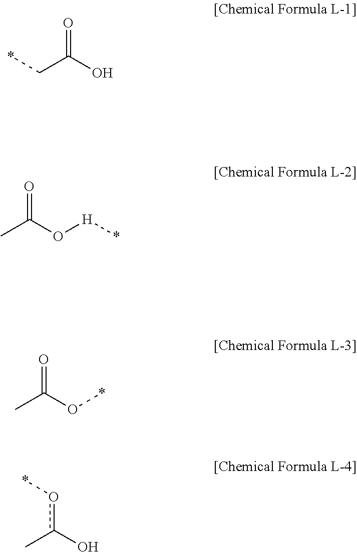

### Comparative Example 2

A photoresist composition was prepared in the same manner as in Comparative Example 1 except that the acetic acid was added in an excessive amount, so that the acetic acid was present as an excess ligand compound.

### Comparative Example 3

A photoresist composition was prepared in the same manner as in Comparative Example 1 except that the acetic acid was added in an excessive amount, and acetylacetone was additionally added in a small amount, such that the acetic acid and the acetylacetone were present as an excess ligand compound.

### Example 1

A photoresist composition was prepared in the same manner as in Comparative Example 2 except that 4-iodo-2-methylphenol was additionally added, such that the acetic acid and the 4-iodo-2-methylphenol were present as an excess ligand compound.

### Example 2

A photoresist composition was prepared in the same manner as in Comparative Example 3 except that 4-iodo-2-methylphenol was additionally added, such that the acetic acid, the acetylacetone, and the 4-iodo-2-methylphenol were present as an excess ligand compound.

### Example 3

A photoresist composition was prepared in the same manner as in Example 1 except that 2-(5-fluoro-2-methoxyphenyl) acetic acid was used instead of the 4-iodo-2-methylphenol, such that the acetic acid and the 2-(5-fluoro-2-methoxyphenyl) acetic acid were present as an excess ligand compound.

### Example 4

A photoresist composition was prepared in the same manner as in Example 2 except that the 2-(5-fluoro-2-methoxyphenyl) acetic acid was used instead of the 4-iodo-2-methylphenol, such that the acetic acid, the acetylacetone, and the 2-(5-fluoro-2-methoxyphenyl)acetic acid were present as an excess ligand compound.

### Example 5

A photoresist composition was prepared in the same manner as in Example 1 except that fluorobenzene was used instead of the 4-iodo-2-methylphenol, such that the acetic acid was present as an excess ligand compound. Herein, the metal compound was represented by Sn(R)₁(X)₃ (R′ as a fluorobenzyl group, and X was acetic acid).

The photoresist compositions of Comparative Examples 1 to 3 and 1 to 5 are represented by each composition shown in Table 1.

TABLE 1

| | | Excess ligand | | |
|---|---|---|---|---|
| | | Ligand not | Ligand | Mixed weight ratio |
| | Organometallic | including a | including a | between excess |
| | compound | halogen | halogen | ligands |
| Comp. | Sn(R)₁X₃ | — | — | — |
| Ex. 1 | (R: butyl X: | | | |
| | acetic acid) | | | |
| Comp. | Sn(R)₁X₃ | acetic acid | — | — |
| Ex. 2 | (R: butyl X: | | | |
| | acetic acid) | | | |
| Comp. | Sn(R)₁X₃ | acetic acid/ | — | acetic |
| Ex. 3 | (R: butyl X: | acetylacetone | | acid:acetylacetone = |
| | acetic acid) | | | 9:1 |
| Ex. 1 | Sn(R)₁X₃ | acetic acid | 4-iodo-2- | acetic acid:4-iodo-2- |
| | (R: butyl X: | | methylphenol | methylphenol = 9:1 |
| | acetic acid) | | | |
| Ex. 2 | Sn(R)₁X₃ | acetic acid/ | 4-iodo-2- | acetic |
| | (R: butyl X: | acetylacetone | methylphenol | acid:acetylacetone:4- |
| | acetic acid) | | | iodo-2-methylphenol = |
| | | | | 9:0.5:0.5 |
| Ex. 3 | Sn(R)₁X₃ | acetic acid | 2-(5-fluoro-2- | acetic acid:2-(5- |
| | (R: butyl X: | | methoxyphenyl)acetic | fluoro-2-methoxy |
| | acetic acid) | | acid | phenyl)aceticacid = 9:1 |
| Ex. 4 | Sn(R)₁X₃ | acetic acid/ | 2-(5-fluoro-2- | acetic |
| | (R: butyl X: | acetylacetone | methoxyphenyl)acetic | acid:acetylacetone:2- |
| | acetic acid) | | acid | (5-fluoro-2- |
| | | | | methoxyphenyl)acetic |
| | | | | acid = 9:0.5:0.5 |
| Ex. 5 | Sn(R′)₁(X)₃ | acetic acid | | — |
| | (R′: | | | |
| | fluorobenzyl | | | |
| | X: acetic acid) | | | |

The photoresist compositions of Comparative Examples 1 to 3 and Examples 1 to 5 were respectively formed into a photoresist material layer and then exposed to EUV light (13.5 nm) and baked to form photoresist patterns.

Based on an exposure dose (100%) when the composition of Comparative Example 2 was formed into a photoresist pattern (pillar pattern), each relative exposure dose of the comparative examples and the example embodiments was compared, and the results are shown in Table 2.

In addition, based on a bar ADI CD (nm) variation ratio (100%) of a photoresist pattern (pillar pattern) formed by using the composition of Comparative Example 1, relative changes over time of the other comparative examples and the example embodiments were compared, and the results are shown in Table 2.

TABLE 2

| | Dose (%) | Change over time (%) |
|---|---|---|
| Comparative Example 1 | 80 | 100 |
| Comparative Example 2 | 100 | 25 |
| Comparative Example 3 | 95 | 25 |
| Example 1 | 85 | 25 |
| Example 2 | 90 | 25 |
| Example 3 | 85 | 25 |
| Example 4 | 90 | 25 |
| Example 5 | 90 | 25 |

As shown in Tables 1 and 2, when a ligand compound included a halogen element, compared with a compound including no halogen element, photosensitivity and stability of a photoresist composition were simultaneously improved.

By way of summation and review, an aspect of the present disclosure provides a photoresist composition that can simultaneously improve the stability and photosensitivity of the photoresist composition. Aspects of the present disclosure further provide a method for fabricating a semiconductor device using the photoresist composition. By using the photoresist composition as described herein, excellent storage stability and high photosensitivity may be satisfied at the same time.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

### DESCRIPTION OF SYMBOLS

1 hydrolysable ligand compound (first ligand compound)
2 photo-dissociable ligand compound (first ligand compound)
3A ligand compound including a halogen element (second ligand compound)
3B ligand compound including a halogen element (first ligand compound)
4 ligand compound not including a halogen element (second ligand compound)
5 moisture and oxygen
10 organometallic compound

What is claimed is:

1. A photoresist composition, comprising:
an organometallic compound including a central metal;
a first ligand compound; and
a second ligand compound; wherein:
the first ligand compound bonds with the central metal,
the second ligand compound does not bond with the central metal, and
the first or second ligand compound includes a halogen element.

2. The photoresist composition as claimed in claim 1, wherein the second ligand compound includes a halogen element.

3. The photoresist composition as claimed in claim 2, wherein the second ligand compound including the halogen element includes at least one selected from an aliphatic carboxyl compound, an aliphatic alkane compound, an aliphatic alcohol compound, an aliphatic ester compound, an aliphatic amine compound, an alicyclic carboxyl compound, an alicyclic alcohol compound, an alicyclic ester compounds, an alicyclic amine compound, an aromatic compound, and a fused ring compound.

4. The photoresist composition as claimed in claim 2, wherein the second ligand compound further includes a ligand compound not including the halogen element in addition to the ligand compound including the halogen element.

5. The photoresist composition as claimed in claim 4, wherein among the second ligand compounds, the ligand compound not including the halogen element includes a heteroatom other than a halogen element.

6. The photoresist composition as claimed in claim 5, wherein the second ligand compound including the heteroatom other than a halogen element includes at least one selected from sulfuric acid, phosphoric acid, an aliphatic carboxyl compound, an aliphatic ketone compound, an aliphatic alcohol compound, an aliphatic ester compound, an aliphatic amine compound, an alicyclic carboxyl compound, an alicyclic ketone compound, an alicyclic alcohol compound, an alicyclic ester compound, an alicyclic amine compound, an aromatic heterocyclic compound, and a fused ring compound.

7. The photoresist composition as claimed in claim 1, wherein the first ligand compound includes a halogen element.

8. The photoresist composition as claimed in claim 7, wherein the first ligand compound including the halogen element includes at least one selected from an aliphatic carboxyl compound, an aliphatic alkane compound, an aliphatic alcohol compound, an aliphatic ester compound, an aliphatic amine compound, an alicyclic carboxyl compound, an alicyclic alcohol compound, an alicyclic ester compound, an alicyclic amine compound, an aromatic compound, and a fused ring compound.

9. The photoresist composition as claimed in claim 8, wherein a carbon atom and/or a heteroatom form a bond with the central metal.

10. The photoresist composition as claimed in claim 7, wherein the first ligand compound further includes a ligand compound not including the halogen element in addition to the ligand compound including the halogen element.

11. The photoresist composition as claimed in claim 10, wherein among the first ligand compounds, the ligand compound not including the halogen element includes a heteroatom other than a halogen element.

12. The photoresist composition as claimed in claim 11, wherein the first ligand compound including the heteroatom other than the halogen element includes at least one selected from sulfuric acid, phosphoric acid, an aliphatic carboxyl compound, an aliphatic ketone compound, an aliphatic alcohol compound, an aliphatic ester compound, an aliphatic amine compound, an alicyclic carboxyl compound, an alicyclic ketone compound, an alicyclic alcohol compound, an alicyclic ester compound, an alicyclic amine compound, an aromatic heterocyclic compound, and a fused ring compound.

13. The photoresist composition as claimed in claim 10, wherein among the first ligand compounds, the ligand compound not including the halogen element is composed only of carbon atoms and hydrogen atoms.

14. The photoresist composition as claimed in claim 13, wherein the first ligand compound composed only of carbon atoms and hydrogen atoms includes at least one selected from an alicyclic compound, an aromatic compound, and a fused ring compound.

15. The photoresist composition as claimed in claim 1, wherein the central metal includes at least one selected from polonium (Po), tellurium (Te), titanium (Ti), lead (Pb), gold (Au), silver (Ag), cesium (Cs), bismuth (Bi), tin (Sn), zinc (Zn), antimony (Sb), indium (In), cadmium (Cd), and astatine (At).

16. The photoresist composition as claimed in claim 1, wherein a total amount of the organometallic compound including the central metal, the first ligand compound, and the second ligand compound is less than or equal to 5 wt % based on a total amount of the photoresist composition.

17. A photoresist composition, comprising:
an organometallic compound including a central metal;
a first ligand compound; and
a second ligand compound,
wherein the first ligand compound bonds with the central metal,
the second ligand compound does not bond with the central metal, and
both the first and the second ligand compounds include a halogen element.

18. The photoresist composition as claimed in claim 17, wherein the first ligand compound includes a ligand compound that includes the halogen element and a ligand compound that does not include the halogen element.

19. The photoresist composition as claimed in claim 17, wherein the second ligand compound includes a ligand compound that includes the halogen element and a ligand compound that does not include the halogen element.

20. A method of fabricating a semiconductor device, the method comprising:
forming a photoresist material layer on a lower layer using a photoresist composition;
performing a first bake on the photoresist material layer;
performing exposure by irradiating a KrF excimer laser, an ArF excimer laser, an F₂ excimer laser, or an EUV light on a partial region of the photoresist material layer where the first bake is performed;
performing a second bake on the photoresist material layer after the exposure;
removing an unexposed portion of the photoresist material layer where the second bake is performed to form a photoresist pattern; and
processing the lower layer using the photoresist pattern,
wherein the photoresist composition includes: an organometallic compound including a central metal; a first ligand compound; and a second ligand compound, the first ligand compound bonds with the central metal, the second ligand compound does not bond with the central metal, and the first ligand compound and/or the second ligand compound include a halogen element.
